(19) United States
(12) Patent Application Publication
(10) Pub. No.: US 2004/0262728 A1
(43) Pub. Date: Dec. 30, 2004

(54) Modular device assemblies

(76) Inventors: Terry L. Sterrett, Cave Creek, AZ (US); Vijay Wakharkar, Paradise Valley, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/611,501

(22) Filed: Jun. 30, 2003

(51) Int. Cl. H01L 23/02

(52) U.S. Cl. 257/678

(57) ABSTRACT

An apparatus including a support substrate comprising a plurality of first support contacts and a plurality of second support contacts on a surface of the support substrate; a chip comprising a plurality of circuits coupled to respective ones of a plurality of externally accessible chip contacts, wherein the chip contacts are coupled to respective ones of the first support contacts; a plurality of fusible masses coupled to respective ones of the plurality of second support contacts; an electrically-insulating encapsulant on the support substrate and the chip. A method including forming a plurality of fusible masses on respective ones of a plurality of externally accessible support contacts on a surface of a support substrate, the substrate further comprising a circuit structure on the surface; and encapsulating a portion of the support substrate and the circuit structure with an electrically insulating encapsulant.

### BACKGROUND

1. Field

Circuit packaging.

2. Background

Circuit dies or chips are commonly provided as individual, pre-packaged units. A typical die has a flat, rectangular shape with a front face having contacts for connection to internal circuitry of the chip. An individual die is typically mounted to a substrate or die carrier (substrate package or support circuit), that in turn is mounted on a circuit panel such as a printed circuit board.

Multichip modules have been developed in which typically, several dies or chips, possibly having related functions, are attached to a common circuit panel and protected by a common package. One advantage to this approach is a conservation of space that might ordinarily be wasted by individual die packages. However, most multichip module designs utilize a single layer of dies positioned side-by-side on a surface of a planar circuit panel. In “flip chip” designs, a face of the die confronts a face of a circuit panel and contacts on the die are bonded to the circuit panel by solder balls or other connecting elements. The flip chip design provides a relatively compact arrangement where each die occupies an area (e.g., an xy plane) of the circuit panel equal to or slightly larger than the area of the die face. The compact arrangement is an example of a chip scale package (CSP).

One type of CSP gaining momentum in the integrated circuit industry is the “stack” CSP. These packages take advantage of multiple application requirements, such as static random access memory (SRAM) and flash memory and combine both dies into one package. However, instead of placing the individual dies side-by-side (such as multichip modules), a stacked CSP is stacked with two or more dies on top of each other to improve space saving.

One type of stacked multichip module connects dies in a z plane through interposer structures. For example, a substrate package including a microprocessor may be connected through an interposer to a substrate package including one or more memory dies. The interposer module may be formed from laminate material in which copper pillars are implanted and serve as an electrical connection to the substrate package of the underlying die (e.g., microprocessor). The manufacture of an interposer module requires multiple assembly operations including laminating the interposer module to a substrate package. In practice, this is proven to be costly and a source of structural failure at the interposer-substrate interface due to poor adhesion.

### BRIEF DESCRIPTION OF THE DRAWINGS

Features, aspects, and advantages of embodiments will become more thoroughly apparent from the following detailed description, appended claims, and accompanying drawings in which:

FIG. 1 shows a schematic, side view of a substrate package for a wire-bonded die having a die-attach adhesive on a surface thereof.

FIG. 2 shows a schematic, top view of the substrate package of FIG. 1.

FIG. 3 shows-a side view of the substrate package of FIG. 1 having a die-attach adhesive thereto.

FIG. 4 shows the substrate package of FIG. I having fusible masses connected to support contacts of the substrate package.

FIG. 5 shows a top view of a structure shown on FIG. 4.

FIG. 6 shows a substrate package of FIG. 1 with encapsulant being introduced thereon.

FIG. 7 shows the substrate package of FIG. 1 following the introduction of encapsulant.

FIG. 8 shows the structure of FIG. 7 aligned with another module.

FIG. 9 shows the structure of FIG. 7 connected to an another module.

FIG. 10 shows a second embodiment of a die on a substrate package with fusible masses contacting package contacts and an encapsulant encapsulating the die.

FIG. 11 shows a plurality of substrate packages on a single support with die-attach adhesive on each package.

FIG. 12 shows the support of FIG. 11 with a plurality of dies connected to respective ones of the substrate packages.

FIG. 13 shows a support of FIG. 11 with fusible masses surrounding each die on respective ones of the substrate packages.

FIG. 14 shows the support of FIG. 11 having a stencil aligned above the support for encapsulant dispensing.

FIG. 15 shows the support of FIG. 11 following the introduction of encapsulant around each die.

FIG. 16 shows the support of FIG. 11 following the singulation of each substrate package.

FIG. 17 shows an embodiment of a substrate package including a die and fusible masses on support contacts with encapsulant encapsulating the die and a portion of the fusible masses.

FIG. 18 shows a module of a second substrate package on the substrate package of FIG. 17.

### DETAILED DESCRIPTION

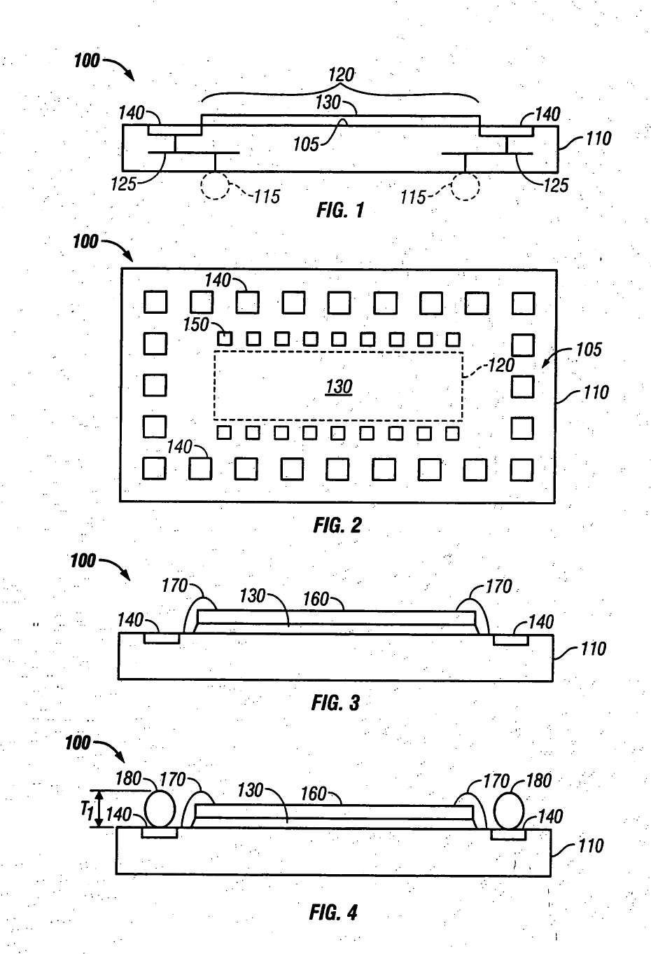

The various packages or package assemblies described herein are suitable, in one aspect, in integrated circuit (IC) packaging to include central processing units (CPUs) and memory units (e.g., flash memory chips) in applications such as stand alone computers, cell phones, and personal digital assistants. FIG. 1 shows a schematic, side view of a support circuit or package substrate as a portion of a package. In this embodiment, package 100 includes package substrate 110 of a laminate material such as a BT laminate that may be used, for example, as a molded matrix array package (MMAP). Substrate 110 also includes a number of first contacts 140 positioned along the periphery of substrate 110 on surface 105. First contacts 140 may be used to connect substrate 110 to other substrates, such as where substrate 110 is part of a multichip module assembly,. or to a circuit panel such as a printed circuit board. FIG. 1 shows signal line 125 disposed within substrate 110 connecting first contacts 140 to a second side of substrate 110, such as to contacts on a second side of substrate 110. FIG. 1 also shows solder balls 115 (shown in ghost lines) that may be used to electrically connect substrate 110 to a circuit panel.

FIG. 1 shows substrate 110.having surface 105 and area 120 for bonding of a circuit chip or die. Overlying. area 120 on surface 105 is die-attach adhesive 130 to connect a die to substrate 110. FIG. 2 shows a top view of substrate 110, showing surface 105. FIG. 2 shows first contacts 140 positioned around a periphery of substrate 110. FIG. 2 also shows area 120 that will accommodate a chip or die. Disposed along a periphery of area 120, in this embodiment, are second contacts. 150 that may be used to electrically connect a chip or die to substrate 110. Second contact points 150 are intended to be connected through wire bonds to contact points on a chip or die over area 120 of substrate 110. Although a package incorporating a wire-bonded die is described, the teachings apply equally to other electrical bonding systems, such as flip chip systems that may use solder to connect a-die to a substrate. FIG. 2 also shows die-attach adhesive 130 covering area 120. Representative die attach adhesives include film and paste materials as commonly used in the field. An example of a suitable film die attach is DF 402″ available from Hitachi Chemical Company, Ltd., and a suitable die attach paste is 2025″ from Ablestick Corporation of Seoul, Korea

FIG. 3 shows the structure of FIG. 1 following the attachment of a die to the substrate. In this illustration, die 160 is physically connected to substrate 110 through die-attach adhesive 130 over area 120. Electrical contacts on die 160 are connected to second contacts 150 through wire bonds 170.

FIG. 4 shows the structure of FIG. 3 following the introduction of fusible masses 180 on first contact points 140. Representatively, fusible masses 180 are a solder material such as tin (Sn) solder material or lead (Pb) solder (e.g., SnPb) material. Fusible masses 180 are dispensed to a thickness, T₁, that is greater than a projected thickness of an encapsulant over die 160. A representative thickness for fusible masses 1 80 of tin solder material is on the order of 100 to 200 microns ( m).

Solder balls are attached to substrate via, for example, a stencil printing processes whereby flux material is printed onto substrate contact pads upon which solder balls are placed. A suitable flux material is Kester TSF-6502″ from Kester Corporation of Des Plaines, Illinois and suitable ball placement equipment is a Vanguard 5020 BGA ball attach machine available from RVSI Vanguard Corporation of Tucson, Arizona.

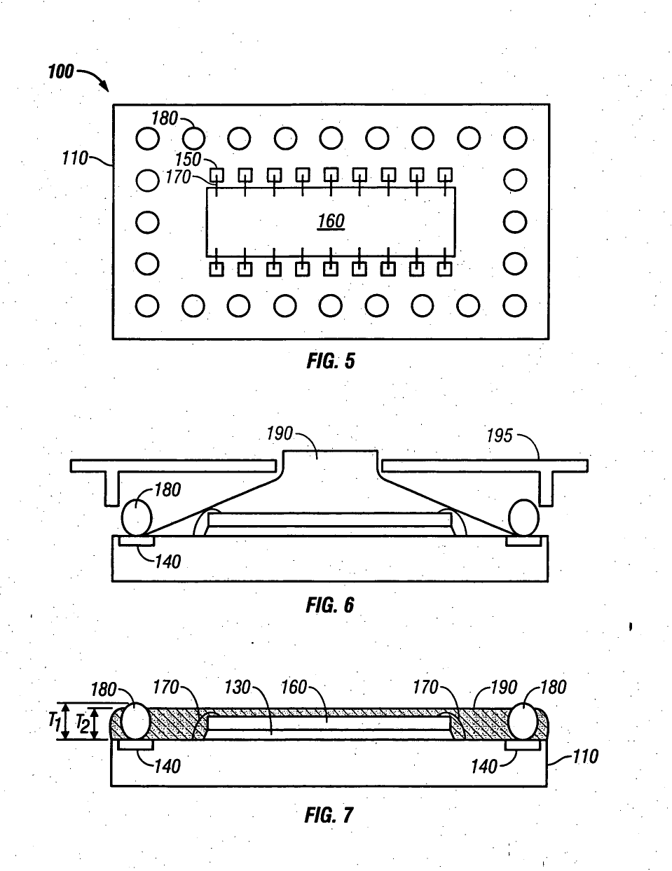

FIG. 5 shows the top view of the structure of FIG. 4. FIG. 5 shows fusible masses 180 on first contacts 140 and die 160 connected to second contacts 150 and substrate 110.

FIG. 6 shows the structure of FIG. 4 and FIG. 5 and illustrates the dispensing of encapsulant material. In this embodiment, encapsulant material 190 is dispensed through stencil 195. Stencil 195 acts a dam to allow encapsulant material to be introduced on die 160 and wire bonds 170 under low pressure, and low speed and laminer flow. Stencil 195 has an opening, in one embodiment, of similar shape but slightly smaller (e.g., 50 percent smaller) than area 120 on substrate 110. Encapsulant flows, in this embodiment, on die 160 and around fusible masses 180. A suitable process for introducing encapsulant 190 is the STENSEAL″ process developed by DEK Printing Machines Ltd., of Weymouth, England and Kulicke and Soffa (K&S) of Willow Grove, Pa. Suitable encapsulants include polymeric materials known as thermosetting epoxies. Preferably, these materials are biphenyl, phenyl epoxy and similar resin chemistries that are cured by amine, anhydride or similar materials. Various properties include viscosity, filler package, and curing chemistries. Suitable materials have viscosity in the range of 10-30 Pa-s, 0 to 70 percent filler concentration (by weight), and cure temperature between 40 to 180 [symbol] C.

FIG. 7 shows the structure of FIG. 6 following the introduction (e.g., dispensing) of encapsulant. FIG. 7 shows encapsulant 190 on substrate 110, including on die 160, and wire bonds 170. Encapsulant 190 also surrounds fusible masses 180, partially encapsulating fusible masses 180. By partially encapsulating fusible masses 180, encapsulant 190 may act as a stress distributing film. In the embodiment shown in FIG. 7, fusible masses 180 are exposed above encapsulant 190. In other words, encapsulant 190 has a thickness, T₂ (measured from substrate surface 105) that is less than thickness, T₁ of fusible masses 180. In one embodiment, T₂ is on the order of 50 to 75 percent of T₁.

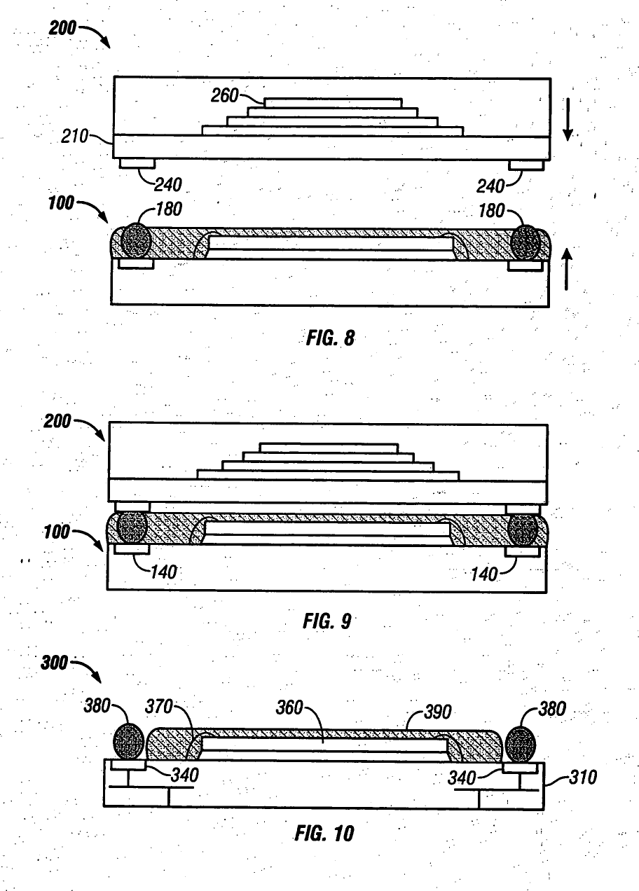

FIG. 8 shows the structure of FIG. 7 aligned with a second structure or module in the process of forming a multichip module structure. Referring to FIG. 8, structure 200 including substrate 210 and one or more dies or chips 260. is positioned on structure 100 described above with reference to FIGS. 1 to 7. Representatively,. contacts 240 are aligned with fusible masses 180. FIG. 9 shows the multichip module with structure 200 connected to structure 100 through fusible masses 180.

FIG. 10 shows another embodiment of a structure utilizing fusible masses to electrically connect assemblies of a multichip module. FIG. 10 shows structure 300 including substrate 310 having die 360 physically and electrically connected thereto. Substrate 310 also includes fusible masses 380 formed on contacts 340. Encapsulant 390 is dispensed so as to encapsulate die 360 and wire bonds 370. Encapsulant 390, in this embodiment, does not partially encapsulate fusible solder masses. This may be accomplished by modifying a stencil so that encapsulant 390 will not flow to fusible masses 380. Alternatively, encapsulant 390 may be placed prior to the introduction of fusible masses 380 and the area on contacts 340 cleared of encapsulant material if necessary. FIG. 10 also shows fusible masses 380 having a. thickness measured from a surface of substrate 310, that is greater than a thickness of encapsulant 390.

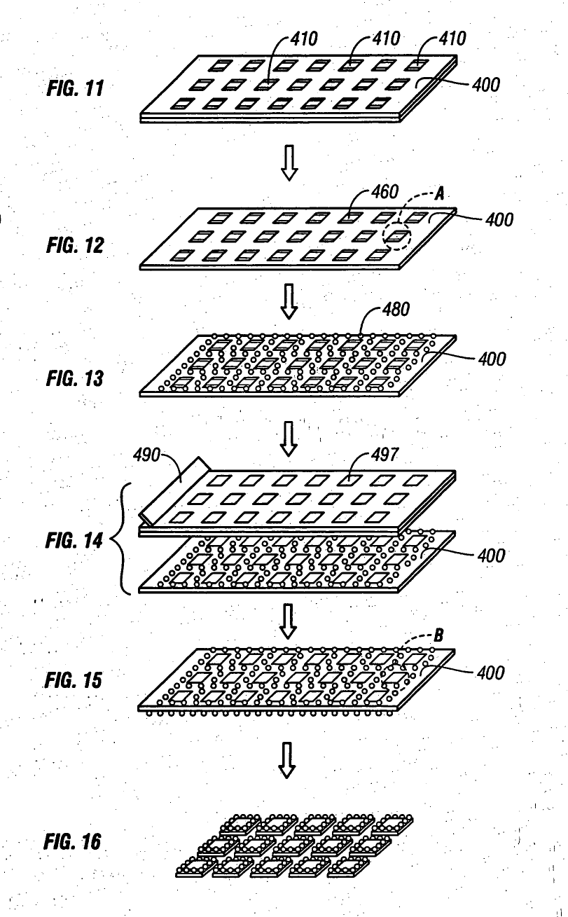

FIGS. 11-16 show a process of forming multiple structures, such as structure 100 (see e.g., FIGS. 1-9) or structure 300 (see FIG. 10). The following process of forming non-singulated structures basically follow the process described above with respect to FIGS. 1-7 and the accompanying text. Therefore, in the context of describing a process of forming non-singulated structures with references to FIGS. 11-16, reference is made to the previous discussion with respect to FIGS. 1-10.

FIG. 11 shows composite substrate 400 having multiple substrates 410, such as laminate substrates formed therein. Each of substrates 410 may have a designated die attach area and contacts formed thereon. A die-attach adhesive may be introduced at the designated die attach area. FIG. 12 shows composite structure 400 following the introduction of dies 460 over respective areas of individual substrates 410 and the electrical connection, through wire bonds 470, of dies 460 to individual substrates.

FIG. 13 shows the structure of FIG. 12 following the introduction of fusible masses such as solder balls on respective substrates. FIG. 14 shows composite structure 400 having stencil 495 aligned over the, composite structure. Stencil 495 is used in the dispensing of encapsulant material. FIG. 14 also shows encapsulant 490. In one embodiment, encapsulant 490 is moved laterally across stencil 495 and flows through openings 497 in stencil 495.

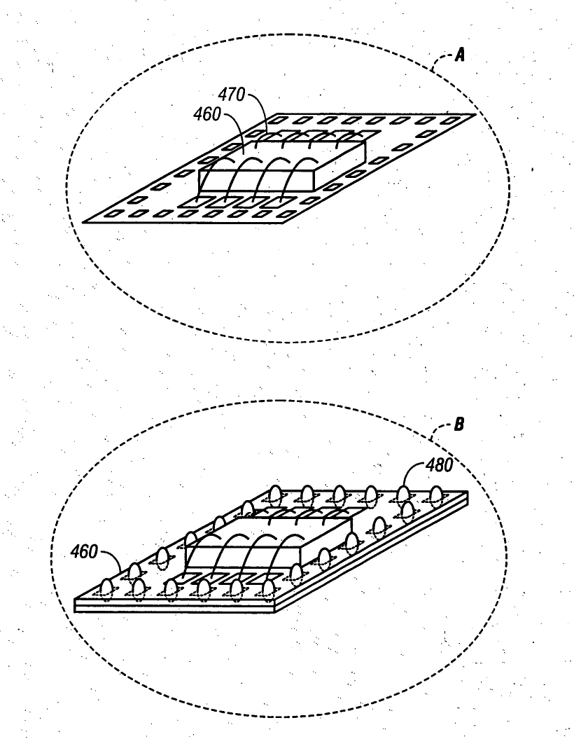

FIG. 15 shows composite structure 400 following the introduction of encapsulant 490 over the composite structure including on individual dies 460 and around fusible masses 480. FIG. 16 shows composite structure 400 following singulation into individual structures.

FIG. 17 shows another embodiment of a structure utilizing fusible masses to electrically connect assembly of a multichip module. FIG. 17 shows structure 500 including substrate 510 having die 560 physically and electrically (through wire bond 570) connected thereto. Substrate 510 also includes fusible masses 580 formed on contacts 540. Encapsulant 590 is dispensed so as to encapsulate die 560 and wire bond 570. Encapsulant 590, in this embodiment, also encapsulates or surrounds 75 to 90 percent of fusible masses 580. Referring to FIG. 17, encapsulant 590 has a thickness, T₂, that is 75 to 90 percent of the thickness, T₁, of fusible masses 580.

Referring to FIG. 17, structure 500 is aligned with a second structure module in the process of forming a multichip module structure. Module 600 includes substrate 610 and one or more dies or chips 660. Representatively, contacts 640 on substrate 610 are aligned with fusible masses 580 of structure 500.

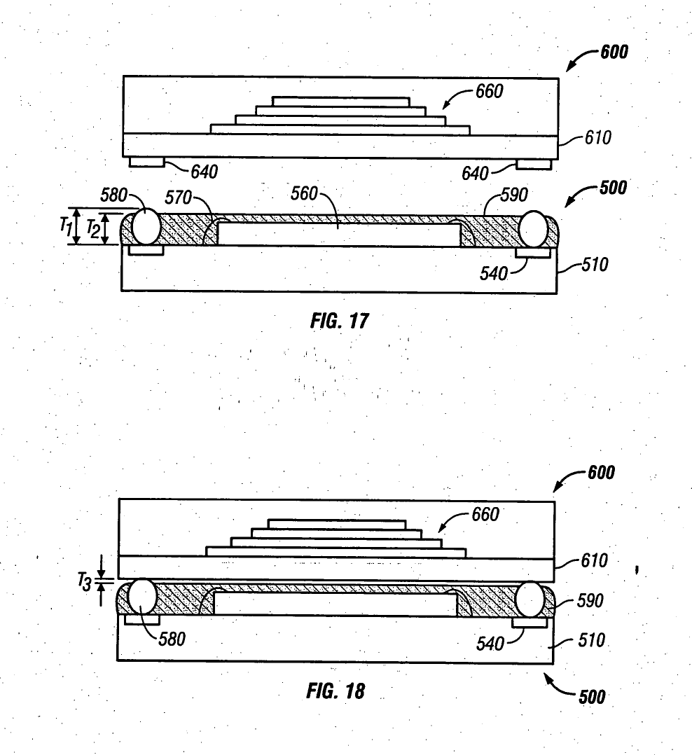

FIG. 18 shows a multichip module with structure 600 connected to structure 500 through fusible masses 680. In this embodiment,.where encapsulant surrounds 75 to 90 percent or more of fusible masses 580, the connection of structure 600 to structure 500 leaves at least minimal gap thickness, T₃, if any, between the connected structures. In another embodiment, the material for encapsulant 590 may be selected so that the material does not set until the structures (e.g., structure 600 and structure 500) are connected together. For example, an encapsulant of a polymer material may be selected such that 60 to 90 percent of a theoretical cross-link density is achieved prior to the connection of substrate 600 to substrate 500 through fusible masses 580. Once the connection is made, encapsulant 590 that is present in an amount sufficient to contact substrate 610 (e.g., T₃ is zero) allows the encapsulant to bond these structures together. A suitable material for encapsulant 590, in this example, is a material that has a curing chemistry such that the material completes its cross-linking reaction at a time and temperature above that it needed for solder metallurgical joint formation.

In the preceding paragraphs, specific embodiments are described. It will, however, be evident that various modifications and changes may be made thereto without departing from the broader spirit and scope of the claims. The specification and drawings are, accordingly, to be regarded in an illustrative rather than a restrictive sense.

1. An apparatus comprising:
a support substrate comprising a plurality of first support contacts and a plurality of second support contacts on a surface of the support substrate;
a chip comprising a plurality of circuits coupled to respective ones of a plurality of externally accessible chip contacts, wherein the chip contacts are coupled to respective ones of the first support contacts;
a plurality of fusible masses coupled to respective ones of the plurality of second support contacts;
an electrically-insulating encapsulant on the support substrate and the chip.

2. The apparatus of claim 1, wherein the plurality of fusible masses have a thickness at least equivalent to the thickness of the encapsulant measured from the surface of the support substrate at one of the plurality of fusible masses.

3. The apparatus of claim 2, wherein the encapsulant is present in an amount to encapsulate the chip and encapsulate a portion of respective ones of the plurality of fusible masses.

4. The apparatus of claim 1, wherein the support substrate is a first support substrate and the plurality of second support contacts are positioned on the first support substrate to align with contacts of a second support substrate.

5. The apparatus of claim 4, wherein the plurality of second supports are positioned around the periphery of the support substrate.

6. The apparatus of claim 1, wherein the support substrate is a first support substrate, the apparatus further comprising a second support substrate comprising a plurality of second support contacts on a surface thereof, the plurality of second support contacts coupled directly to respective ones of the plurality of fusible masses.

7. An apparatus comprising:
a first support substrate comprising at least one circuit structure and a plurality of first support contacts on a first surface thereof, the plurality of first support contacts electrically coupled to respective ones of circuits of the at least one circuit structure;
a plurality of fusible masses on respective ones of the plurality of first support contacts;
an electrically-insulating encapsulant on the first support substrate and on the at least one circuit structure;
a second support substrate comprising at least one circuit structure on a first surface thereof and having a plurality of second support contacts on a second surface thereof and coupled to respective ones of the plurality of fusible masses, the plurality of second support contacts electrically coupled to respective ones of circuits of the at least one circuit structure.

8. The apparatus of claim 7, wherein the at least one circuit structure on the first support substrate comprises a microprocessor and the at least one circuit structure on the second support substrate comprises a memory.

9. The apparatus of claim 7, wherein the plurality of fusible masses have a thickness at least equivalent to the thickness of the encapsulant measured from the surface of the first support substrate at one of the plurality of fusible masses.

10. The apparatus of claim 2, wherein the encapsulant is present in an amount to encapsulate the circuit structure and encapsulate a portion of respective ones of the plurality of fusible masses.

11. The apparatus of claim 7, wherein the plurality of support contacts of the first support substrate are positioned around the periphery of the first support substrate.

12. A method comprising:
forming a plurality of fusible masses on respective ones of a plurality of externally accessible support contacts on a surface of a support substrate, the substrate further comprising a circuit structure on the surface; and
encapsulating a portion of the support substrate and the circuit structure with an electrically insulating encapsulant.

13. The method of claim 13, wherein encapsulating further comprises encapsulating less than an entire portion of each of the plurality of fusible masses.

14. The method of claim 13, wherein encapsulating further comprises encapsulating on the order of 75 percent to 90 percent of each of the plurality of fusible masses.

15. The method of claim 12, wherein the support substrate comprises a first support substrate, the method further comprising, coupling a second support substrate to the first support substrate through the plurality of fusible masses.
